(19) United States
(12) Patent Application Publication
(10) Pub. No.: US 2025/0204113 A1
(43) Pub. Date: Jun. 19, 2025

(54) DISPLAY PANEL, MANUFACTURING METHOD THEREOF, AND DISPLAY APPARATUS

(71) Applicant: Shanghai Tianma Micro-electronics Co., Ltd., Shanghai (CN)

(72) Inventors: Qijun YAO, Shanghai (CN); Quanpeng YU, Shanghai (CN)

(21) Appl. No.: 18/623,260

(22) Filed: Apr. 1, 2024

(30) Foreign Application Priority Data
Dec. 13, 2023 (CN) 202311717424.5

(51) Int. Cl. H01L 33/62; H01L 25/075; H01L 33/38

(52) U.S. Cl. CPC H10H 20/857; H01L 25/0753; H10H 20/8312

(57) ABSTRACT

A display panel includes a base substrate, a light-emitting unit, and a first film layer. The light-emitting unit is located over one side of the base substrate. One surface of the light-emitting unit away from the base substrate has a central area and an edge area. At least a portion of the edge area surrounds the central area. The first film layer has an opening exposing the light-emitting unit. In a direction perpendicular to a plane of the base substrate, at least a portion of the first film layer overlaps with the edge area. A display apparatus includes a display panel. The display panel includes a base substrate, a light-emitting unit, and a first film layer.

### CROSS-REFERENCE TO RELATED APPLICATION

This application claims priority to Chinese Patent Application No. 202311717424.5, filed on Dec. 13, 2023, the entire content of which is incorporated herein by reference.

### TECHNICAL FIELD

The present disclosure relates to the field of display technology and, in particular, to a display apparatus and a manufacturing method thereof.

### BACKGROUND

Light Emitting Diode (LED) is an optoelectronic semiconductor component that can convert current into a specific wavelength range. Its light-emitting principle is that the energy difference, originated from an electron moving between an n-type semiconductor and a p-type semiconductor, releases energy in a form of light. Thus, a light-emitting diode is called a cold light source that has advantages of low power consumption, small size, high brightness, good matching with integrated circuits, and high reliability. The light-emitting diode is widely used as a light source. Moreover, with the development of LED technology, technologies directly using an LED as a self-luminous display pixel of a LED display panel or a Micro LED display panel have gradually been widely applied.

Among them, the Micro LED display panel combines technical characteristics of Thin Film Transistor-Liquid Crystal Display (TFT-LCD) and LED display. Its display principle is to miniaturize and array the LED structure design with a thin film. Then, the Micro LED is transferred from an original growth substrate to another substrate, for example, using mass transfer technology.

In a display panel in which a vertically structured Micro LED is connected to a base substrate, since one electrode of the Micro LED is led out from one side away from the base substrate, planarization is required after mass transfer to fill up a gap between Micro LEDs. However, this structure is prone to a poor electrical connection, such as open circuits or short circuits.

### SUMMARY

One aspect of the present disclosure provides a display panel. The display panel includes a base substrate, a light-emitting unit, and a first film layer. The light-emitting unit is located over one side of the base substrate. One surface of the light-emitting unit away from the base substrate has a central area and an edge area. At least a portion of the edge area surrounds the central area. The first film layer has an opening exposing the light-emitting unit. In a direction perpendicular to a plane of the base substrate, at least a portion of the first film layer overlaps with the edge area.

One aspect of the present disclosure provides a display apparatus. The display apparatus includes a display panel. The display panel includes a base substrate, a light-emitting unit, and a first film layer. The light-emitting unit is located over one side of the base substrate. One surface of the light-emitting unit away from the base substrate has a central area and an edge area. At least a portion of the edge area surrounds the central area. The first film layer has an opening exposing the light-emitting unit. In a direction perpendicular to a plane of the base substrate, at least a portion of the first film layer overlaps with the edge area.

Another aspect of the present disclosure provides a method of forming a display panel. The method includes arranging a base substrate, placing a light-emitting unit over one side of the base substrate, and forming a first film layer. One surface of the light-emitting unit away from the base substrate has a central area and an edge area, and at least a portion of the edge area surrounds the central area. The first film layer has an opening exposing the light-emitting unit. In a direction perpendicular to the plane of the base substrate, at least a portion of the first film layer overlaps with the edge area.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure.

In order to better illustrate embodiments of the present disclosure or technical solutions in related technologies, the drawings to be used in the description of the embodiments or the related technologies will be briefly demonstrated below. Obviously, for those persons of ordinary skill in the art, other drawings can be obtained based on the illustrated drawings without exerting creative labor.

FIG. 1 illustrates a schematic structural diagram of a display panel.

FIG. 2 illustrates a schematic structural diagram of a display panel according to various embodiments of the present disclosure.

FIG. 3 illustrates a schematic structural diagram of another display panel according to various embodiments of the present disclosure.

FIG. 4 illustrates a schematic structural diagram of a light-emitting unit according to various embodiments of the present disclosure.

FIG. 5 illustrates a schematic structural diagram of another display panel according to various embodiments of the present disclosure.

FIG. 6 illustrates a schematic structural diagram of another display panel according to various embodiments of the present disclosure.

FIG. 7 illustrates a schematic structural diagram of another display panel according to various embodiments of the present disclosure.

FIG. 8 illustrates a schematic structural diagram of another display panel according to various embodiments of the present disclosure.

FIG. 9 illustrates a schematic structural diagram of another display panel according to various embodiments of the present disclosure.

FIG. 10 illustrates a schematic structural diagram of another display panel according to various embodiments of the present disclosure.

FIG. 11 illustrates a schematic structural diagram of another display panel according to various embodiments of the present disclosure.

FIG. 12 illustrates a schematic structural diagram of another display panel according to various embodiments of the present disclosure.

FIG. 13 illustrates a schematic structural diagram of another display panel according to various embodiments of the present disclosure.

FIG. 14 illustrates a schematic structural diagram of another display panel according to various embodiments of the present disclosure.

FIG. 15 illustrates a schematic structural diagram of another display panel according to various embodiments of the present disclosure.

FIG. 16 illustrates a schematic structural diagram of another display panel according to various embodiments of the present disclosure.

FIG. 17 illustrates a schematic structural diagram of another display panel according to various embodiments of the present disclosure.

FIG. 18 illustrates a schematic structural diagram of another display panel according to various embodiments of the present disclosure.

FIG. 19 illustrates a schematic structural diagram of another display panel according to various embodiments of the present disclosure.

FIG. 20 illustrates a schematic structural diagram of another display panel according to various embodiments of the present disclosure.

FIG. 21 illustrates a schematic structural diagram of another display panel according to various embodiments of the present disclosure.

FIG. 22 illustrates a schematic structural diagram of another display panel according to various embodiments of the present disclosure.

FIG. 23 illustrates a schematic structural diagram of a display apparatus according to various embodiments of the present disclosure.

FIG. 24 illustrates a schematic flowchart of a manufacturing method of a display panel according to various embodiments of the present disclosure.

FIG. 25 illustrates a schematic structural diagram of a base substrate provided by S51 in the manufacturing method shown in FIG. 24.

FIG. 26 illustrates a schematic structural diagram formed by S52 in the manufacturing method shown in FIG. 24.

FIG. 27 illustrates a schematic structural diagram formed by S53 in the manufacturing method shown in FIG. 24.

FIG. 28 illustrates a schematic flowchart of another manufacturing method of a display panel according to various embodiments of the present disclosure.

FIG. 29 illustrates a schematic structural diagram after forming a flat layer in the manufacturing method shown in FIG. 28.

FIG. 30 illustrates a schematic structural diagram after forming a signal line in the manufacturing method shown in FIG. 28.

FIG. 31 illustrates a schematic structural diagram after forming a second film layer in the manufacturing method shown in FIG. 28.

FIG. 32 illustrates a schematic structural diagram after a flat layer is thickly coated in the manufacturing method according to various embodiments of the present disclosure.

### DETAILED DESCRIPTION OF THE EMBODIMENTS

In order to better convey above objects, features, and advantages of the present disclosure, technical solutions of the present disclosure will be further described below. It should be noted that, as long as there is no conflict, embodiments of the present disclosure and the features in the embodiments can be combined with each other.

Many specific details are set forth in the following description to fully understand the present disclosure. However, the present disclosure can also be implemented in other ways different from those described here. Obviously, embodiments in the present disclosure are only part of embodiments of the present disclosure, not all embodiments.

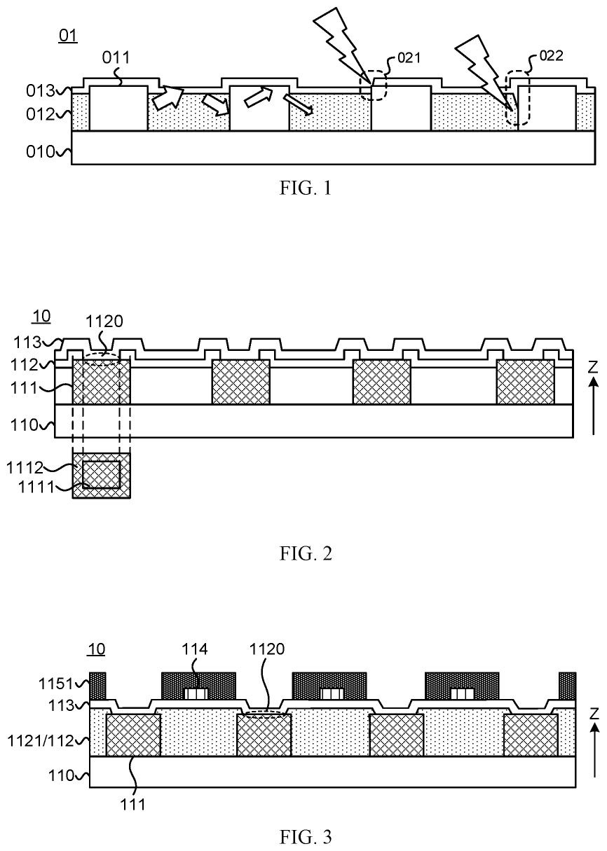

In view of technical issues demonstrated in the background, the present disclosure illustrates that a flat layer under this structure has a pit at an edge of a light-emitting unit, resulting in a short circuit, or an edge step of the light-emitting unit is broken, resulting in an open circuit. An exemplary explanation is given in conjunction with FIG. 1.

FIG. 1 illustrates a schematic structural diagram of a display panel. As shown in FIG. 1, a display panel 01 includes a base substrate 010, a light-emitting unit 011 located over one side of the base substrate 010, and a flat layer 012 filled in a gap between adjacent light-emitting units 011 for flattening. The flat layer 012 exposes a top of the light-emitting unit 011 to facilitate an electrical connection between a common electrode 013 and the light-emitting unit 011. As indicated by 021 and 022 in FIG. 1, since a cleavage surface of an edge of the light-emitting unit 011 (such as Micro LED) is relatively sharp, there can have reverse chamfering. The flat layer 012 can develop a pit at an edge of the light-emitting unit 011 after grayscale treatment. Forming a common electrode 013 directly after the flat layer 012 will cause a short circuit between the common electrode 013 and an exposed electrode in the pit. Please refer to the structure shown in 022. At the same time, the common electrode 013 fabricated at a reverse chamfered edge of the light-emitting unit 011 is prone to disconnection in the step area, leading to a circuit breakage issue. Please refer to the structure shown in 021 for understanding. In addition, since it is difficult for the common electrode 013, the flat layer 012, and a semiconductor layer of the light-emitting unit 011 to have a same refractive index, a light emitted from a side surface of the light-emitting unit 011 will be reflected back and forth inside the structure, as shown by the arrows in FIG. 1, which will cause low light efficiency.

To address at least one of the above issues, embodiments of the present disclosure provide a display panel in which a first film layer is used to cover and protect an edge area of a light-emitting unit, thereby addressing an occurrence of pits in a peripheral material layer (such as the flat layer) of the light-emitting unit to resolve the short circuit between the common electrode and other electrodes related to the light-emitting unit. At the same time, the disconnection of the common electrode in the step area at the edge of the light-emitting unit is addressed.

The display panel, the display apparatus including the display panel, and the manufacturing method of the display panel provided by embodiments of the present disclosure will be exemplified below with reference to the accompanying drawings.

FIG. 2 is a schematic structural diagram of a display panel according to various embodiments of the present disclosure. Referring to FIG. 2, the display panel 10 includes a base substrate 110, a light-emitting unit 111, and a first film layer 112, optionally also including a common electrode 113 located over the side of the first film layer 112 away from the base substrate 110.

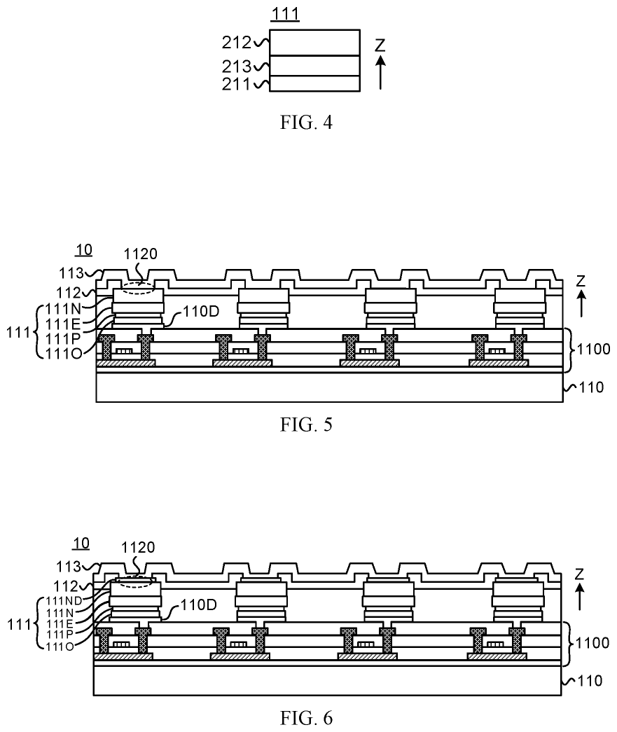

The light-emitting unit 111 is located over one side of the base substrate 110. The base substrate 110 can support and electrically connect the light-emitting unit 111. On the one hand, it can stabilize an overall structure of the display panel 10. On the other hand, it can provide a driving signal to the light-emitting unit 111 to drive the light-emitting unit 111 to emit light, thereby achieving lighting or display. Exemplarily, the base substrate 110 can be any circuit substrates known to those persons of ordinary skill in the art that can provide a driving signal to the light-emitting unit. The light-emitting unit 111 can be an LED, such as a Micro LED, a Mini LED, or LEDs of other sizes known to those persons of ordinary skill in the art, which are not limited here. In the following, a film structure of the light-emitting unit and the base substrate will be exemplified with reference to FIG. 4 to FIG. 6.

The light-emitting unit 111 over one surface away from the base substrate 110 includes a central area 1111 and an edge area 1112 at least partially surrounding the central area 1111. For example, taking the orientation shown in FIG. 2 as an example, one surface of the light-emitting unit 111 away from the base substrate 110 is an upper surface of the light-emitting unit 111. It can be understood that the division of the central area 1111 and the edge area 1112 is for convenience in explaining the relative positional relationship between the first film layer 112 and the light-emitting unit 111.

The first film layer 112 is provided with an opening 1120 that exposes the light-emitting unit 111. In a direction perpendicular to a plane of the base substrate 110 (such as a preset direction Z shown in FIG. 2), at least a portion of the first film layer 112 and the edge area 1112 overlap. As a result, the first film layer can cover the edge of the light-emitting unit 111 and expose the central area 1111 of the light-emitting unit 111. Thus, the central area 1111 is used to realize the electrical connection between the light-emitting unit 111 and the common electrode 113. Since the edge of the light-emitting unit 111 is covered by the first film layer 112, the issue of pit occurring on the edge of the light-emitting unit 111 is addressed. This further addresses the issue of upper and lower electrode short circuits between the common electrode 113 and other electrodes related to the light-emitting unit 111. At the same time, the issue of the step area breakage at the edge of the light-emitting unit 111 of the common electrode 113 is addressed.

For example, the first film layer 112 can be a flat layer 1121, as shown in FIG. 3. The flat layer 1121 includes the opening 1120 that exposes the central area of the light-emitting unit 111. In the direction perpendicular to the plane of the base substrate 110 (for example, the preset direction Z shown in FIG. 3), at least a portion of the flat layer 1121 overlaps the edge area of the light-emitting unit 111 to cover the edge of the light-emitting unit 111 and address issues of short circuit and open circuit. In some embodiments, the display panel 10 shown in FIG. 3 can further include a signal line 114 (e.g., a metal wire) located over one side of the common electrode 113 away from the base substrate 110 and a light-shielding layer 1151 for covering the signal line 114.

Alternatively, the light-shielding layer can be provided first and then the common electrode. In the structure of the display panel, the first film layer can be at least one of the flat layer and the light-shielding layer, which will be exemplified below with reference to the accompanying drawings.

It should be noted that FIG. 2 and FIG. 3 only illustrate that the display panel 10 includes four light-emitting units 111, which is only a local structure of the display panel 10 and does not limit the display panel 10. At the same time, FIG. 2 only illustrates that the surface of the light-emitting unit 111 away from the base substrate 110 is a quadrangular shape, which does not limit the shape of the light-emitting unit 111.

In some embodiments, based on FIG. 2, the first film layer 112 is organic.

Among them, the first film layer 112 is used to cover the edge of the light-emitting unit 111. By setting the first film layer 112 to be an organic substance, the first film layer 112 can better cover the edge of the light-emitting unit 111 and help ensure better heat resistance and stability.

For example, the organic substance can be a transparent organic substance, such as a transparent resin. Thus, covering the edge of the light-emitting unit 111 while minimizing the impact on the light exiting of the light-emitting unit 111 can reduce the impact on the display effect of the display panel 10.

In some embodiments, the first film layer 112 can also be an organic/inorganic composite film layer, which is not limited here.

In some embodiments, FIG. 4 is a schematic structural diagram of a light-emitting unit according to various embodiments of the present disclosure. Based on FIG. 2, referring to FIG. 4, in the display panel 10, the light-emitting unit 111 includes a first-type semiconductor layer 211, a second-type semiconductor layer 212, and the light-emitting layer 213 located between the first-type semiconductor layer 211 and the second-type semiconductor layer 212. The second-type semiconductor layer 212 is located over one side of the light-emitting layer 213 away from the base substrate 110. Combining the orientations shown in FIGS. 2 and 4, the first-type semiconductor layer 211 is blow the light-emitting layer 213, and the second-type semiconductor layer 212 is over the light-emitting layer 213.

Among them, the first-type semiconductor layer 211 and the second-type semiconductor layer 212 are one of P-type layer and N-type layer respectively. For example, the first-type semiconductor layer 211 is a P-type layer, and the second-type semiconductor layer 212 is an N-type layer. In some embodiments, the first-type semiconductor layer 211 is an N-type layer, and the second-type semiconductor layer 212 is a P-type layer. When a voltage is applied to the light-emitting unit 111 (i.e., a driving current is provided), the a hole provided by the P-type layer and an electron provided by the N-type layer recombine in the light-emitting layer 213 to generate a self-radiated light. Thus, self-illumination of the light-emitting unit 111 is realized to achieve the image display of the display panel 10.

For example, specific structures and materials of the first-type semiconductor layer 211, the second-type semiconductor layer 212, and the light-emitting layer 213 can be any one or more type known to those persons of ordinary skill in the art, and are not limited here.

In some embodiments, FIG. 5 is a schematic structural diagram of a display panel according to various embodiments of the present disclosure. On the basis of FIG. 2 and FIG. 4, with reference to FIG. 5, the display panel 10 also includes a common electrode 113. The common electrode 113 is located over one side of the first film layer 112 away from the base substrate 110, as well as over one side of the second-type semiconductor layer 212 away from the base substrate 110. The common electrode 113 is electrically connected to the light-emitting unit 111 through the opening 1120. Specifically, the common electrode 113 can directly contact the second-type semiconductor layer 212 to achieve electrical connection with the light emitting unit 111.

For example, with reference to FIGS. 4 and 5, the first-type semiconductor layer 211 can be an N-type layer 111N, the second-type semiconductor layer 212 can be a P-type layer 111P, and the light-emitting layer 213 can be a quantum well structure 111E. For example, it can be a multi-layer quantum well structure. The common electrode 113 is in direct contact with the N-type layer 111N to achieve electrical connection with the light-emitting unit 111. Optionally, the P-type layer 111P is connected to the base substrate 110 through an ohmic contact layer 111O and a eutectic electrode 110D. For example, the ohmic contact layer 111O can be a first electrode of the light-emitting unit 111. The eutectic electrode 110D can be formed over one side of the base substrate for achieving eutectic bonding electrical connection with the light-emitting unit 111. For example, the first electrode 111O and the eutectic electrode 110D can be bonded and electrically connected through a eutectic layer (not shown in the figure). In some embodiments, when the light-emitting unit 111 and the base substrate 110 are electrically connected in other ways, the eutectic electrode 110D can be substituted with other types of electrical connection structures, which is not limited here.

In some embodiments, FIG. 6 is a schematic structural diagram of a display panel according to various embodiments of the present disclosure. The display panel shown in FIG. 6 and the display panel shown in FIG. 5 are same structure and will not be described again here. The difference is that in the display panel 10 shown in FIG. 6, the light-emitting unit also includes an electrode layer. The electrode layer is located over one side of the second-type semiconductor layer away from the base substrate. The electrode layer can be in direct contact with the common electrode to achieve electrical connection between the common electrode and the light-emitting unit. For example, the electrode layer can be an N-electrode layer 111ND. Therefore, the light-emitting unit 111 can include a P-type layer 111P, a multilayer quantum well structure 111E, an N-type layer 111N, and N-electrode layer 111ND that are sequentially stacked in a direction away from the base substrate 110. The common electrode 113 is in direct contact with the N-electrode layer 111ND to electrically connect the light emitting unit 111.

In some embodiments, when the second-type semiconductor layer is a P-type layer, the electrode layer can also be a P-electrode layer. Thus, the electrical connection between the light-emitting unit and the common electrode is realized through the contact between the P-electrode layer and the common electrode.

It should be noted that FIG. 6 only exemplarily shows that in the direction parallel to the plane of the base substrate (i.e., the direction perpendicular to the preset direction Z), a width of the electrode layer (for example, the N-electrode layer) is smaller than a width of the second-type semiconductor layer (for example, the N-type layer 111N). In the direction perpendicular to the plane of the base substrate (i.e., the predetermined direction Z), at least a portion of the first film layer 112 overlaps with the electrode layer. In some embodiments, in the direction parallel to the plane of the base substrate, the width of the electrode layer can equal to the width of the second-type semiconductor layer. And/or, in the direction perpendicular to the plane of the base substrate, at least a portion of the first film layer overlaps with the second-type semiconductor layer but does not overlap with the electrode layer.

In some embodiments, continuing to refer to FIG. 5 or FIG. 6, a refined film layer structure of a driving film layer 1100 over the base substrate 110 is also shown. For example, the driving film layer 1100 is located over one side of the base substrate 110 facing the light-emitting unit 111. The driving film layer 1100 can include a driving circuit provided for the light-emitting unit 111, represented by a thin film transistor (TFT) in the figure. It is shown that the driving circuit is electrically connected to the light-emitting unit 111 in a one-to-one correspondence to achieve driving control of the light-emitting unit 111 so that the light-emitting unit 111 at the corresponding position emits light according to the preset brightness, thereby causing the display panel 10 to display an image. In some embodiments, the driving circuit in the base substrate 110 can also include other structures, such as capacitors, which are not limited here.

As shown in FIG. 5 or FIG. 6, the driving film layer 1100 over the base substrate 110 can include a semiconductor layer, a gate layer, a source and drain electrode layer, and an insulating layer used to separate adjacent film layers. In some embodiments, the base substrate 110 can also include other functional film layers, such as an impurity blocking layer, a flat layer covering the driving circuit, etc., which are not limited here.

It should be noted that FIGS. 4 to 6 only illustrate the film structure of the light-emitting unit 111. In some embodiments, the light-emitting unit 111 can also include other functional film layers such as a semiconductor buffer layer and a current spreading layer, which are not limited here.

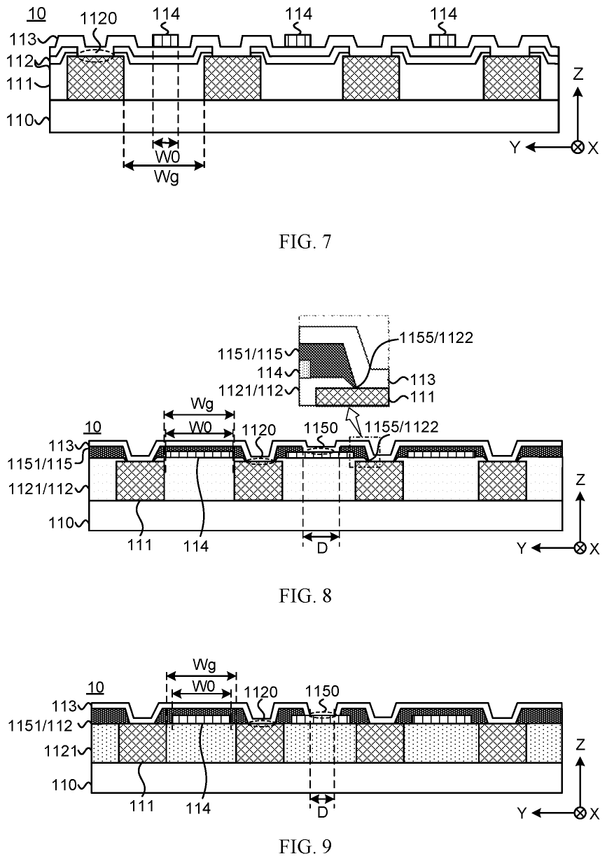

In some embodiments, FIG. 7 is a schematic structural diagram of a display panel according to various embodiments of the present disclosure. Referring to FIG. 7, the display panel 10 can also include a signal line 114, which can be located between at least some adjacent light-emitting units 111 without blocking the light-emitting unit 111, thereby avoiding influencing the light emitted by the light-emitting unit 111. At the same time, the signal line 114 can be electrically connected to the common electrode 113 to reduce the voltage drop of the common electrode 113 at different positions in the display panel 10. This improves the consistency of the common signal provided by the common electrode 113 at different positions in the display panel 10, thereby improving the display effect.

For example, the material of the common electrode 113 can be a transparent metal oxide, and the signal line 114 can be a metal wire or other conductive material due to the conductivity of the common electrode 113.

In some embodiments, FIG. 3 and FIGS. 8 to 11 also show that the display panel includes a signal line. The difference between different embodiments lies in the film layer sequence, the film layer position of the signal line 114, the implementation of the first film layer 112, or the microstructure setting of the first film layer 112 are different, which will be exemplarily explained below with reference to different drawings.

In some embodiments, continuing to refer to FIG. 7, in the display panel 10, the spacing between adjacent light-emitting units 111 is Wg. The signal line 114 extends along the first direction X, and the width of the signal line 114 along the second direction Y is W0. The second direction Y is perpendicular to the first direction X, and both are perpendicular to the preset direction Z mentioned above. Among them, (⅓)Wg≤W0<Wg.

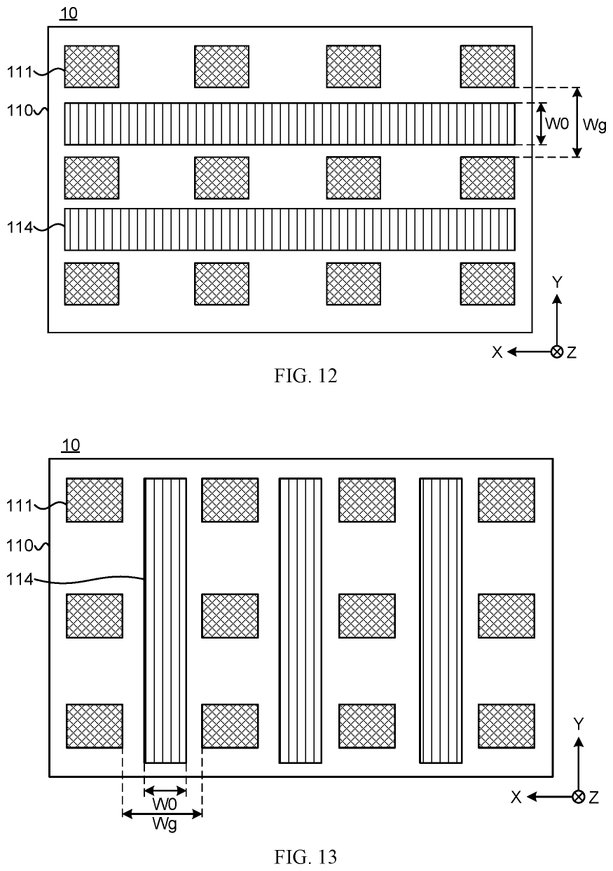

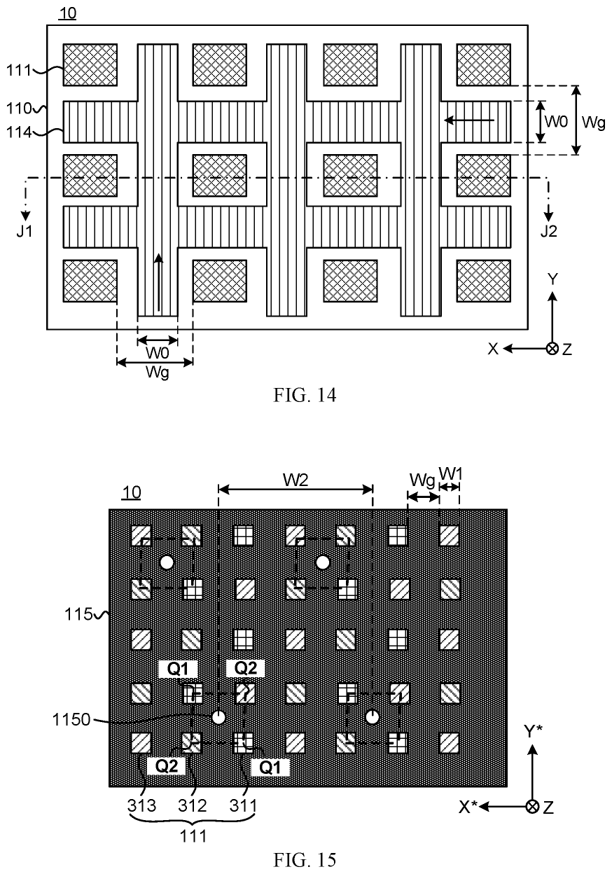

In embodiments of the present disclosure, the plane determined by the first direction X and the second direction Y is parallel to the plane of the base substrate 110. The first direction X and the second direction Y can be one of the transverse direction and the longitudinal direction. The signal line 114 extends along the transverse direction and is arranged along the longitudinal direction. The line width of the signal line 114 is its width along the longitudinal direction, as shown in FIG. 12. Alternatively, the first direction X is the longitudinal direction, the second direction Y is the transverse direction. The signal line 114 extends along the longitudinal direction and is arranged along the transverse direction, and the line width of the signal line 114 is its width along the transverse direction, as shown in FIG. 13. In other embodiments, the signal line 114 can also be distributed in a grid shape, in which case the line width direction intersects with the local extension direction of the signal line, as shown in FIG. 14.

It can be understood that FIG. 7 can be regarded as a schematic cross-sectional structural diagram of the display panel 10 along J1J2 shown in FIG. 14. FIG. 14 only exemplarily shows the base substrate 110, the light emitting unit 111, and the signal line in the display panel 10. Other structures can be understood with reference to other embodiments and will not be described again here. In addition, the display panel structure that satisfies the above-mentioned relative size relationship between the spacing between adjacent light-emitting units and the line width of the signal line can also have a cross-sectional structure as shown in any of FIGS. 8 to 11, which is not limited here.

In embodiments of the present disclosure, a wide line width of the signal line 114 results in a small resistance of the signal line 114. Therefore, by setting the lower limit of the line width of the signal line 114 to (⅓)Wg, the line width of the signal line 114 is relatively wide to reduce resistance. This reduces a signal consistency difference at different locations on the display panel. In addition, the arrangement of the signal line 114 does not affect the light exiting of the light-emitting unit 111. Therefore, the signal line 114 needs to be arranged between the light-emitting units 111, and the maximum line width needs to be smaller than the spacing Wg between the light-emitting units 111. Thus, it avoids affecting the light exiting of the light-emitting unit 111 and ensures the light exiting effect and the overall display effect of the display panel 10.

For example, the line width of the signal line 114 may be (⅓)Wg, (½)Wg, (⅔)Wg, (⅘)Wg≤W0≤( 13/15)Wg, (⅓)Wg≤W0<Wg or other width values or width range values, which are not limited here.

In embodiments of the present disclosure, the width of the signal line 114 can be understood as a width of a projection of the signal line 114 on the plane of the base substrate 110.

In some embodiments, the stacking sequence of the first film layer, the common electrode, and the signal line in the display panel can be the first film layer, the common electrode, and the signal line sequentially arranged along a direction away from the base substrate.

For example, continuing to refer to FIG. 3 or FIG. 7, the signal line 114 can be located over the side of the common electrode 113 away from the first film layer 112. As shown in FIG. 3, the first film layer 112 can be a single film layer, such as a flat film layer 1121. In some embodiments, as shown in FIG. 7, the first film layer 112 can also be a composite film layer composed of two film layers. In some embodiments, the first film layer can also be a layer having three or more films, which is not limited here.

As shown in FIG. 3, in the display panel 10 provided by embodiments of the present disclosure, since the signal line 114 is in direct contact with the common electrode 113, a light-shielding layer 1151 can completely cover the signal line 114 without the need to provide a via hole. That means the via hole exposing the signal line 114 is not arranged in the light-shielding layer 1151, preventing the signal line 114 from reflecting light at the location of the via hole and subsequently affecting the display effect.

In some embodiments, the stacking sequence of the first film layer, the common electrode, and the signal line in the display panel can be the first film layer, the signal line, and the common electrode sequentially arranged along the direction away from the base substrate.

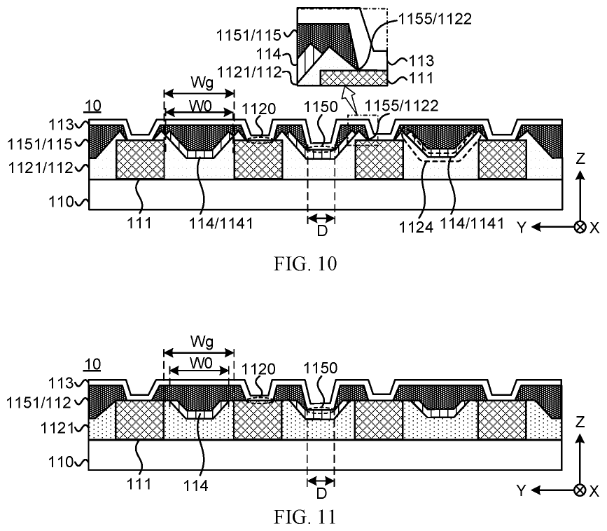

Exemplarily, continuing to refer to FIG. 8 or FIG. 10, the signal line 114 is located between the common electrode 113 and the first film layer 112. The display panel 10 also includes a second film layer 115. The second film layer 115 is located between the signal line 114 and the common electrode 113. The second film layer 115 includes a via hole 1150. The common electrode 113 and the signal line 114 are electrically connected through the via hole 1150.

In embodiments of the present disclosure, the signal line 114 and the common electrode 113 are separated by the second film layer 115. By arranging a via hole 1150 penetrating along the preset direction Z in the second film layer 115, the common electrode 113 and the signal line 114 contacts at the position of the via hole 1150 to achieve electrical connection between the common electrode 113 and the signal line 114 through the via hole 1150.

In some embodiments, based on FIGS. 8 to 11, a transmittance of the second film layer 115 is less than a transmittance of the first film layer 112. In this way, the first film layer 112 can be used to cover the edge of the light-emitting unit 111 without affecting the light exiting of the light-emitting unit 111. In addition, the second film layer 115 can be used to block the signal line 114 to improve the impact of the light emitting of the signal line 114 on the display effect.

As the second film layer 115 is located over the side of the signal line 114 away from the base substrate 110, by setting the transmittance of the second film layer 115 to be relatively small, the second film layer 115 can be used to block the signal line 114. This addresses the issue that the signal line 114 reflects light visible to the naked eye and affects the display effect.

For example, as shown in FIG. 8 or FIG. 10, the first film layer 112 can be a flat layer 1121. The second film layer 115 can be a light-shielding layer 1151.

In some embodiments, the light-shielding layer 1151 can also be used as the first film layer 112. In this case, the upper surface of the flat layer 1121 can be flush with the upper surface of the light-emitting unit 111, as shown in FIG. 9 or FIG. 11. In other embodiments, when the light-shielding layer 1151 is used as the first film layer 112, the upper surface of the flat layer 1121 can also be lower than the upper surface of the light-emitting unit 111.

In some embodiments, the flat layer 1121 and the light-shielding layer 1151 can also be used together as the first film layer 112. In this arrangement, the edge area of the light-emitting unit 111 is covered with two organic film layers, and the light-shielding layer 1151 can be used as a mask layer for the flat layer 1121. The process difficulty is low and the edge of the light-emitting unit is prevented from affecting the electrical connection, thereby improving the electrical connection performance.

In some embodiments, continuing to refer to FIG. 8 or FIG. 10, in the direction perpendicular to the plane of the base substrate 110 (i.e., the preset direction Z shown in the figure), at least a portion of the second film layer 115 overlaps with the edge area of the light-emitting unit 111.

In embodiments of the present disclosure, since the common electrode 113 is located over the side of the second film layer 115 away from the base substrate 110, by covering the edge area of the light-emitting unit with the second film layer 115, the issue of pits occurring at the edge of the light-emitting unit 111 can be improved. This further addresses the issue of short circuits of upper and lower electrode between the common electrode 113 and other electrodes related to the light-emitting unit 111. At the same time, the step area breakage of the common electrode 113 at the edge of the light-emitting unit 111 is resolved to address the breakage issue.

In some embodiments, in order to account for the light effect of the light-emitting unit 111, while the first film layer 112 overlap with the second film layer 115 at the edge area, a small proportion of edge area in the light-emitting unit leads to a large proportion of the central area. That means a large proportion of the light-emitting area leads to a decreased influment on the light efficiency.

For example, in the light-emitting unit, along a direction from the central area to the edge area, a ratio of a width of the central area to a width of the edge area is equal to or greater than 7. For example, when the width of the light-emitting unit is on the order of ten microns, the width of the edge area can be in the micron level. Specifically, the width of the light-emitting unit is 10 microns, and the width of the edge area can be 1 micron.

In some embodiments, other ratios may be used to set the relative sizes of the central area and the edge area, which are not limited here.

In some embodiments, continuing to refer to FIG. 8 or FIG. 10, the second film layer 115 includes a first edge 1155 located over the light emitting unit 111. The first film layer 112 includes a second edge 1122 located over the light emitting unit 111. The position of the first edge 1155 is same as the position of the second edge 1122, that is, the positions of the first edge 1155 and the second edge 1122 over the light-emitting unit 111 coincide.

The first film layer 112 and the second film layer 115 have a same edge over the light-emitting unit 111. That is, in the direction perpendicular to the plane of the base substrate 110, the first edge 1155 and the second edge 1122 are flush. In some embodiments, in any directions parallel to the plane of the base substrate 110, the distance from the first edge 1155 to the edge of the light-emitting unit 111 is equal to the distance from the second edge 1122 to the edge of the light-emitting unit 111.

The second film layer 115 is over one side of the first film layer 112 away from the base substrate 110, and the transmittance of the second film layer 115 is less than the transmittance of the first film layer 112. Therefore, the second film layer 115 can be used as a mask to pattern the first film layer 112 so that the first film layer 112 has an opening 1120 that exposes the light-emitting unit 111. The first film layer 112 covers the edge area of the light-emitting unit 111 to address the issue of electrode short circuit and open circuit. At the same time, using the second film layer 115 of the display panel 10 as a mask can avoid additional configured masks, which is beneficial to reducing process difficulty and cost.

In embodiments of the present disclosure, the first film layer 112 and the second film layer 115 are used to cover the edge area of the light-emitting unit 111. The edges of the first film layer 112 and the second film layer 115 are same, which is beneficial to simplifying the panel structure and the manufacturing process.

In some embodiments, FIG. 15 is a schematic structural diagram of a display panel according to various embodiments of the present disclosure. Referring to FIG. 15, in the display panel 10, the light-emitting unit 111 includes a plurality of first light-emitting units 311, a plurality of second light-emitting units 312, and a plurality of third light-emitting units 313. The first light-emitting unit 311, the second light-emitting unit 312, and the third light-emitting unit 313 forms a virtual quadrilateral. The virtual quadrilateral includes a first virtual quadrilateral (shown as a dotted box in FIG. 15). The first light-emitting unit 311 is located at a first vertex Q1 of the first virtual quadrilateral. The second light-emitting unit 312 and the third light-emitting units 313 are respectively located at a second vertex Q2 of the first virtual quadrilateral. The first vertex Q1 and the second vertex Q2 are alternately and spaced apart. The via hole 1150 is located in the first virtual quadrilateral.

The light-emitting units 111 can be arranged along two intersecting directions. As shown in FIG. 15, the light-emitting unit 111 can be arranged along the third direction X* and the fourth direction Y* that intersect each other. The light-emitting unit 111 arranged along the third direction X* intersect with the light-emitting unit 111 arranged along the fourth direction Y* to define a first virtual quadrilateral. The light-emitting units 111 at the two vertices of one diagonal are identical. For example, they are both the first light-emitting units 311, and the light-emitting units 111 located at the two vertices of another diagonal line are different. For example, they are the second light-emitting unit 312 and the third light-emitting unit 313 respectively. The via hole 1150 is located inside a portion of the first virtual quadrilateral, but not located on the edge of the first virtual quadrilateral. That means the via hole 1150 is located in the intersection gap, and is not located in the line connecting adjacent light-emitting units 111 in the third direction X* or the fourth direction Y*. Moreover, the distances between the via hole 1150 and each vertex of the first virtual quadrilateral are all equal. Thus, the distance between the via hole 1150 and each light-emitting units 111 constituting the first virtual quadrilateral that the via hole 1150 is located are relatively far. Therefore, this reduces the impact of a reflection of the via hole on the light existing effect of the light-emitting unit 111, and prevents the influence on the display effect of the display panel 10.

Moreover, the first light-emitting unit 311, the second light-emitting unit 312, and the third light-emitting unit 313 emit lights in different colors to achieve color mixing for display.

For example, the colors of emitted lights of the first light-emitting unit 311, the second light-emitting unit 312, and the third light-emitting unit 313 are respectively one of red, green, and blue, and each being different. This delivers color display.

In some embodiments, the first light-emitting unit 311 can be a green light-emitting unit. The second light-emitting unit 312 and the third light-emitting unit 313 can be one of red and blue light-emitting units, respectively, and different from each other. Alternatively, the first light-emitting unit 311 can be a blue light-emitting unit, and the second light-emitting unit 312 and the third light-emitting unit 313 can be one of red and green light-emitting units, respectively, and different from each other. In another scenario, the first light-emitting unit 311 can be a red light-emitting unit. The second light-emitting unit 312 and the third light-emitting unit 313 can be one of green and blue light-emitting units, respectively, and different from each other.

In some embodiments, the light-emitting unit 111 can be arranged differently. The via hole 1150 can be positioned inside a minimum polygon defined by the light-emitting units 111 arranged along different directions. The light-emitting units 111 at the vertices of the minimum polygon may be any light-emitting units known by those persons of ordinary skill in the art, and are not specifically limited here.

In some embodiments, as shown in FIG. 15, the distances between the via hole 1150 and the vertices of the first virtual quadrilateral are equal. This arrangement ensures that the visual impact of reflections of signal line at the location of the via hole 1150 on the various light-emitting units 111 is uniform, promoting visual balance.

In some embodiments, as shown in FIG. 15, the light-emitting unit 111 in the display panel 10 is spaced apart along the third direction X* and/or the fourth direction Y*, where the third direction X* and the fourth direction Y* intersect, such as perpendicularly. Along the third direction X* or the fourth direction Y*, the width of an individual light-emitting unit 111 is denoted as W1, the distance between adjacent two via holes 1150 is denoted as W2, and the gap between adjacent light-emitting units 111 is denoted as Wg. Here, W2≥3×(W1+Wg).

The distance between adjacent two via holes 1150 is the distance from the center of one via hole 1150 to the center of another via hole 1150.

Additionally, the width of an individual light-emitting unit 111 can be understood as the maximum width of the light-emitting unit 111 along the third direction X* or fourth direction Y*. For example, when the shape of the light-emitting unit 111 is a quadrilateral, the width of the light-emitting unit 111 is the side length in the corresponding direction. When the shape of the light-emitting unit 111 is circular, the width of the light-emitting unit 111 is the diameter in the corresponding direction. When the shape of the light-emitting unit 111 is another shape known to those persons of ordinary skill in the art, the width of the light-emitting unit 111 is the distance between two boundary points in the corresponding direction. The distance between adjacent light-emitting units 111 is the interval distance along the corresponding direction, i.e., the closest distance, as shown in FIG. 15. Based on this, W1+Wg can also represent the distance between the centers of adjacent two light-emitting units 111.

In the present disclosure, the via hole 1150 is used to connect the signal line 114 and the common electrode 113 because the signal line 114 can be a grid structure and can be configured to be connected across the entire surface. The common electrode 113 can also be configured to be connected across the entire surface. The common electrode 113 achieves the effect of impedance reduction by connecting to the signal line 114 through the via hole 1150. In the present disclosure, by setting W2≥3×(W1+Wg), the distance between the via holes 1150 is relatively large. The distribution of the via hole 1150 in the plane can be sparse, thereby weakening the visual visibility and ensuring the display effect.

For example, as shown in FIG. 15, along the third direction X* or fourth direction Y*, the adjacent via holes 1150 can be spaced apart by 3 rows/columns of light-emitting units 111. In some embodiments, the adjacent via holes 1150 can also be spaced apart by 4 rows/columns, 5 rows/columns, 10 rows/columns, or other quantities of light-emitting units 111, without limitation.

In some embodiments, the via hole 1150 can also be staggeringly set along the third direction X* and/or fourth direction Y* to make the via holes 1150 are staggered in the plane as a whole, thereby reducing the reflection effect of the signal line 114 at a location of the via hole 1150 and weakening the visual visibility.

For example, taking the orientation shown in FIG. 15 as an example, the top-left via hole 1150 is positioned between the first column of light-emitting unit 111 and the second column of light-emitting unit 111. The bottom-left via hole 1150 is positioned between the second column of light-emitting unit 111 and the third column of light-emitting unit 111, offsetting by one column from the top-left via hole 1150. In other embodiments, the via hole 1150 can be staggeringly set in other ways, without elaboration and limitation.

In other embodiments, the via hole 1150 can be regularly distributed, such as having an equal distance between adjacent via holes 1150. The via hole 1150 can be irregularly distributed, such as having unequal distances between at least some adjacent via holes 1150, without limitation.

In some embodiments, based on FIG. 15, an emission wavelength of the first light-emitting unit 311 is smaller than emission wavelengths of the second light-emitting unit 312 and the third light-emitting unit 313.

Among them, a short the light-emission wavelength of the light-emitting unit 311 leads to a low light extraction efficiency. Thus, the light-emitting unit 311 with a small wavelength can be arranged close to the via hole 1150. The signal line 114 at the position of the via hole 1150 can be used to reflect light. The light emitted from one side of the light-emitting unit 111 is reflected once or multiple times, and finally emerges from the light-emitting side of the light-emitting unit 311 facing the light-emitting surface of the display panel. This balances a light-emitting effect between light-emitting units of different colors. Therefore, by arranging a larger number of first light-emitting units 311 around the via hole 311, the light efficiency of the first light-emitting unit 311 can be improved, thereby balancing the overall display effect of the display panel 10 and weakening the impact of the via hole 1150 on the display effect.

Exemplarily, the first light-emitting unit 311 is a blue light-emitting unit, and the second light-emitting unit 312 and the third light-emitting unit 313 are each one of the red light-emitting unit and the green light-emitting unit. Thus, by placing the via hole 1150 close to the blue light-emitting unit, i.e., the quantity of via holes near the blue light-emitting unit is greater than the quantity of via holes near the red (or green) light-emitting unit. This balances the overall display effect of the display panel 10 and mitigates the impact of the via hole 1150 on the display effect.

In some embodiments, when the distribution of the via holes 1150 is sparse enough and/or an aperture D of the via hole 1150 is small, the relative positional relationship between the via hole 1150 and light-emitting units 111 of different emission colors can be arbitrarily set in other ways known to those persons of ordinary skill in the art, without limitation.

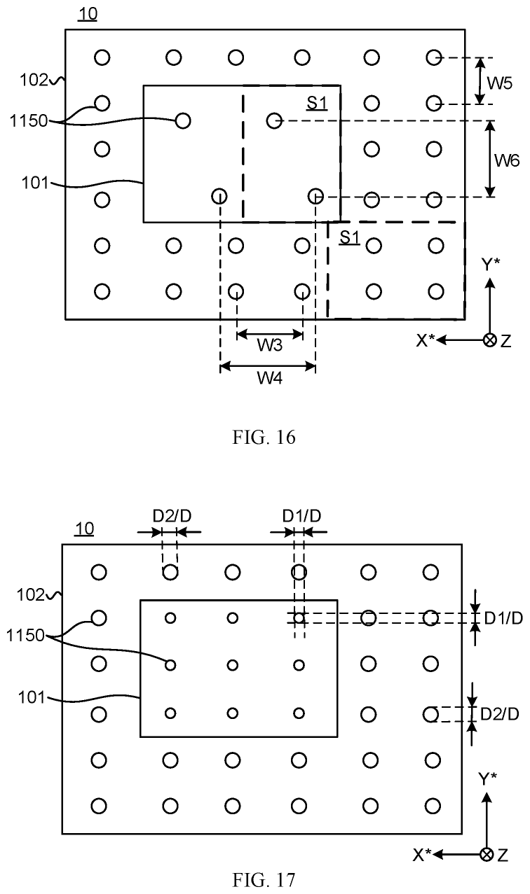

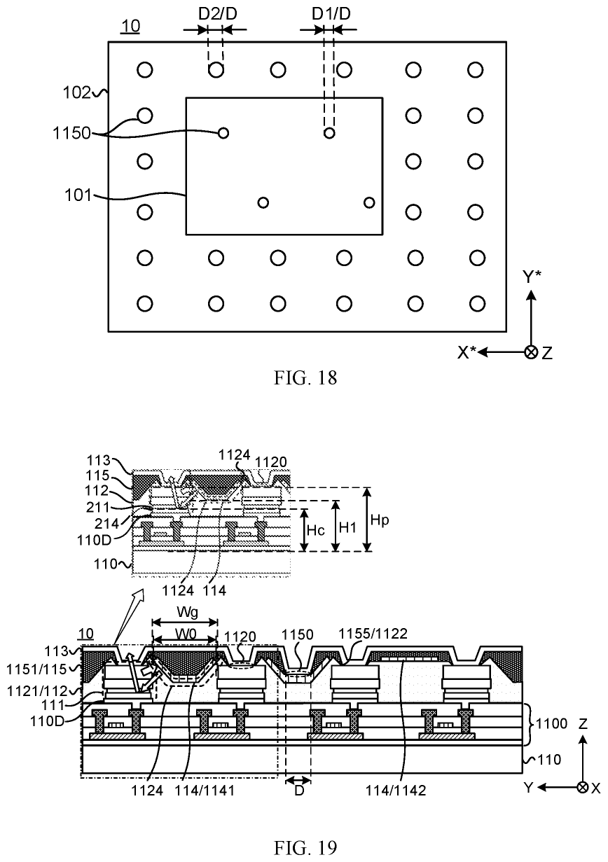

In some embodiments, FIG. 16 provides a schematic structural diagram of a display panel according to various embodiments of the present disclosure. FIG. 17 provides a schematic structural diagram of a display panel according to various embodiments of the present disclosure. FIG. 18 provides a schematic structural diagram of a display panel according to various embodiments of the present disclosure. Referring to FIG. 16, FIG. 17, or FIG. 18, the display panel 10 includes a central display area 101 and an edge display area 102 at least partially surrounding the central display area 101. A distribution density of via holes 1150 in the central display area 101 is less than a distribution density of via hole 1150 in the edge display area 102, as shown in FIG. 16 or FIG. 18. In some embodiments, the aperture D1 of via hole 1150 in the central display area 101 is smaller than an aperture D2 of via hole 1150 in the edge display area 102, as shown in FIG. 17 or FIG. 18.

In the present disclosure, the central display area 101 is the main display area. The density of via hole 1150 is set to be denser in the edge display area 102. While the via holes in the central display area 101 are sparser. In some embodiments, the via hole 1150 in the edge display area 102 is large, while the via hole in the central display area 101 is small. This ensures effective and stable electrical connection between the signal line and the common electrode while mitigating the impact of the via hole 1150 on the display effect.

The distribution density of via holes 1150 can be understood as the quantity of via holes 1150 distributed per unit area. For example, FIG. 16 illustrates a unit area S1, where the quantity of via holes 1150 in the central display area 101 within the unit area S1 is 2. The quantity of via holes 1150 in the edge display area 102 within the unit area S1 is 4. In other embodiments, the distribution density of via holes 1150 can be other density values or ranges, satisfying the above relative size relationship.

Optionally, the distribution density of the via holes 1150 can also be represented by the distance between adjacent via holes 1150. A large distribution density of via holes 1150 can also be interpreted as a small distance between adjacent via holes 1150. Exemplarily, as shown in FIG. 16, along the third direction X*, the distance between adjacent via holes 1150 in the edge display area 102 can be represented as W4. The distance between adjacent via holes 1150 in the central display area 101 can be represented as W3, and satisfies W4>W3. In some embodiments, along the fourth direction Y*, the distance between adjacent via holes 1150 in the edge display area 102 can be represented as W5. The distance between adjacent via holes 1150 in the central display area 101 can be represented as W6, and satisfies W6>W5. This also makes the distribution density of via holes 1150 in the central display area 101 smaller than the distribution density of via holes 1150 in the edge display area 102, thereby avoiding the impact of the via hole 1150 on the display effect.

In some embodiments, the central display area 101 is the main display area. A small distribution density of via holes 1150 leads to a small impact on the display effect. A large distribution density of via holes 1150 leads to an excellent electrical connection performance between the signal line and the common electrode. Based on this, by setting the distribution density of via holes 1150 in the central display area 101 to be smaller than the distribution density of via holes 1150 in the edge display area 102, effective and stable electrical connection between the signal line and the common electrode is ensured, while mitigating the impact of the via hole 1150 on the display effect.

In some embodiments, when the display panel is of a small size, such as for a watch panel, the via hole can be arranged only in the edge display area to ensure the display effect.

In some embodiments, when the distribution density of via holes 1150 is sufficiently small, i.e., when the via holes 1150 are sufficiently sparse and the impact on the display effect can be neglected, the distribution density of via holes 1150 in the edge display area 102 and the central display area 101 can be same.

The aperture of the via hole 1150 can be interpreted as the width of the via hole 1150 in any direction in the plane defined by the third direction X* and the fourth direction Y*. Exemplarily, as shown in FIG. 17 or FIG. 18, when the shape of the via hole 1150 is circular, the aperture of the via hole 1150 is the diameter of the circle. In some embodiments, when the shape of the via hole 1150 is square, the aperture of the via hole 1150 can be the side length of the square. When the shape of the via hole 1150 is other than circular or square, the aperture of the via hole 1150 can be characterized by other characteristic lengths.

In the present disclosure, the central display area 101 is the main display area. A small aperture of the via hole 1150 leads to a small impact on the display effect. A large aperture of the via hole 1150 leads to an excellent electrical connection performance between the signal line and the common electrode. Based on this, by setting the aperture D1 of the via hole 1150 in the central display area 101 to be smaller than the aperture D2 of the via hole 1150 in the edge display area 102, effective and stable electrical connection between the signal line and the common electrode is ensured, while mitigating the impact of via hole 1150 on the display effect.

In some embodiments, when the aperture of the via hole 1150 is small enough, i.e., when the via hole 1150 is small enough and the impact on the display effect can be ignored, the apertures of the via hole 1150 in the edge display area 102 and the central display area 101 can be the same.

In some embodiments, the distribution density and/or aperture of the via hole 1150 in the display panel 10 can also exhibit a gradient trend. For example, the distribution density of the via hole 1150 is greater, i.e., via hole 1150 distribution is denser, when it is closer to the edge of the display panel. Conversely, the distribution density of the via hole 1150 is smaller, i.e., via hole 1150 distribution is sparser, when it is closer to the center of the display panel. In some embodiments, when it is close to the edge of the display panel, the aperture of the via hole 1150 is relatively large. While it is close to the center, the aperture of the via hole 1150 is relatively small.

In some embodiments, based on FIG. 8 to FIG. 11, referring to FIG. 17 or FIG. 18, in the display panel 10, the aperture D of the via hole 1150 satisfies: (⅕)W0≤D≤(⅘)W0. W0 represents the line width of the signal line 114. It can be understood that the aperture D in the present disclosure includes the aperture D2 of the via hole in the edge display area 102 and the aperture D1 of the via hole in the central display area 101.

The via hole 1150 is used to achieve electrical connection between the signal line 114 and the common electrode 113. A large aperture D of the via hole 1150 leads to a large contact area between the signal line 114 and the common electrode 113, an excellent electrical connection performance, and a good stability.

In some embodiments, at the location of the via hole 1150, where the second film layer 115 cannot cover the signal line 114, the signal line 114 at that location can reflect incident ambient light into the display panel. Therefore, to avoid the impact of this reflective effect on the display effect, it is preferable for the aperture D of the via hole 1150 to be small. Specifically, a small aperture D of the via hole 1150 leads to a weak reflective effect of the signal line 114 at the location on ambient light and a small impact on the display effect.

Exemplarily, the aperture D of the via hole 1150 can be (⅕)W0, (⅘)W0, (⅓)W0, (½)W0, (¾)W0, (⅕)W0≤D≤( 7/10)W0, (¼)W0≤D≤(⅘)W0, or other width values or width range values.

In the present disclosure, by setting the aperture D of the via hole 1150 relative to the line width W0 of the signal line 114 to satisfy: (⅕)W0≤D≤(⅘)W0, the impact on the display effect is mitigated while ensuring effective and stable electrical connection between the signal line 114 and the common electrode 113.

In some embodiments, FIG. 19 shows another schematic diagram of a display panel provided in the present disclosure. Referring to FIG. 10 or FIG. 19, the first film layer 112 includes a concave structure 1124. The signal line 114 includes a first signal line 1141, and the first signal line 1141 is located over at least a portion of the side surface of the concave structure 1124.

In some embodiments, the concave structure 1124 can be interpreted as a structure formed by the first film layer 112 recessing toward one side of the base substrate 110. That is, the side of the first film layer 112 away from the light-emitting unit 111 is not a flat surface. It can be exemplified as a bent or folded surface. Exemplarily, FIG. 10 and FIG. 19 can both be viewed as cross-sectional views of the display panel 10 along a plane perpendicular to the base substrate 110. In these figures, the first film layer 112 includes a portion covering the edge area of the light-emitting units 111 and a portion located between adjacent light-emitting units 111. These two portions have different heights relative to the plane of the base substrate 110.

Exemplarily, with respect to the plane of the base substrate 110, that is, the base substrate 110 plane is used as a reference plane, the maximum height of the first film layer 112 covering the edge area of the light-emitting unit 111 is relatively large, while the minimum height of the first film layer 112 located between adjacent light-emitting units 111 is relatively small. From the position of the maximum height to the position of the minimum height, the height of the first film layer 112 gradually decreases, corresponding to the formation of a concave structure 1124 on the side surface.

Exemplarily, in the manufacturing process, the concave structure 1124 can be naturally formed based on a thin coating of the first film layer 112. In some embodiments the concave structure 1124 can be formed based on photolithography after a thick coating.

The signal line 114 can be a metal wire capable of reflecting light. As indicated by an arrow in FIG. 19, when the light exited from the light-emitting unit 111 is incident on the signal line 114 located on the side of the concave structure 1124. That portion of light is reflected back to the light-emitting unit 111 by the signal line 114 and emitted after being reflected by the reflective electrode (e.g., co-crystal electrode) in the light-emitting unit 111, thereby enhancing light efficiency.

By setting the first film layer 112 to include the concave structure 1124 and placing the first signal line 1141 over at least a portion of the side surface of the concave structure 1124, a spotlight effect can be achieved to enhance light efficiency.

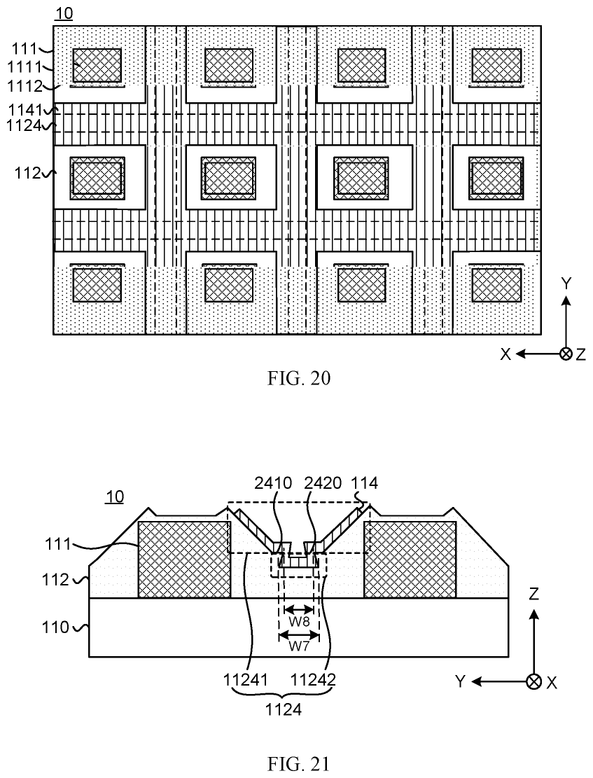

In some embodiments, the concave structure 1124 may include a bottom surface and a side surface. At least a portion of the side surface surrounds the bottom surface. Exemplarily, FIG. 20 shows the boundary position between the bottom surface and the side surface. In this structure, the first signal line 1141 can cover at least a portion of the side surface. Optionally, the first signal line 1141 can cover the entire side surface and bottom surface. This can not only enhance light efficiency but also increase the overall area of the signal line 114, which reduces resistance and improves signal consistency. Simultaneously, it is advantageous for increasing the connection area between the signal line 114 and the common electrode 113, thereby improving electrical performance.

In some embodiments, continuing with reference to FIG. 19, the signal line 114 can also include a second signal line 1142, where the second signal line 1142 is located over the flat surface of the concave structure and electrically connected to the first signal line 1141. Thus, it connects to the common electrode 113, reduces the resistance of the common electrode 113, and improves signal consistency.

Exemplarily, the first film layer 112 can be a flat layer, and the formation of the concave structure 1124 in the flat layer will be exemplified later in conjunction with the manufacturing method of the display panel.

In some embodiments, continuing with reference to FIG. 20, the concave structure 1124 is uniformly distributed on the display panel 10.

The concave structure 1124, in conjunction with the first signal line 1141, achieve a spotlight effect, which enhances the light efficiency of the light-emitting unit 111. Accordingly, by uniformly distributing the concave structure 1124 across the display panel 10, the light efficiency of the light-emitting units 111 at different locations on the display panel can be uniformly improved, thereby uniformly enhancing the display effect of the display panel and ensuring good display consistency.

It can be understood that FIG. 20 exemplarily illustrates a local structure of the display panel 10. In the overall structure of the display panel 10, the concave structure 1124 and the first signal line 1141 located inside the concave structure can be configured in various directions around each light-emitting unit 111. In other embodiments, the concave structure 1124 can be uniformly distributed in other ways, and this is not limited here.

In some embodiments, FIG. 21 provides another schematic diagram of the display panel according to the present disclosure. Referring to FIG. 21, in the display panel 10, the concave structure 1124 include a first concave structure 11241 and a second concave structure 11242. The second concave structure 11242 is located on one side of the first concave structure 11241 close to the base substrate 110. The width W8 of one side of the second concave structure 11242 away from the base substrate 110 is smaller than the width W7 of one side of the second concave structure 11242 close to the base substrate 110.

The second concave structure 11242 has an opening 2420 on one side away from the base substrate 110, and the first concave structure 11241 has a bottom surface 2410 on one side close to the base substrate 110. The opening 2420 of the second concave structure 11242 connects to the bottom surface 2410 of the first concave structure 11241, allowing the second concave structure 11242 and the first concave structure 11241 to be communicated, forming an integral concave structure 1124.

The width of the first concave structure 11241 on the side away from the base substrate 110 is greater than the width of the first concave structure 11241 on the side close to the base substrate 110, specifically designed as a top-cut structure. Exemplarily, the first film layer 112 has a cross-section. The plane of the cross-section is perpendicular to the plane of the base substrate 110. In the cross-section, the width of the first concave structure 11241 on the side away from the base substrate 110 is greater than the width of the first concave structure 11241 on the side close to the base substrate 110. The width of the first concave structure 11241 is the width of the first concave structure 11241 in a plane parallel to the plane of the base substrate 110. Furthermore, along the direction away from the base substrate 110, the width of the first concave structure 11241 gradually increases. The side surface of the first concave structure 11241 is configured with a signal line 114, which can reflect the light emitted from a portion of the side surface of the light-emitting unit 111 back to the light-emitting unit by the reflective electrode, and the light is emitted after being reflected by the reflective electrode. The second concave structure 11242 is configured as a bottom-cut structure. Exemplarily, the first film layer 112 has a cross-section. The plane of the cross-section is perpendicular to the plane of the base substrate 110. In the cross-section, the width of the second concave structure 11242 on the side away from the base substrate 110 is smaller than the width of the second concave structure 11242 on the side close to the base substrate 110. Furthermore, along the direction away from the base substrate 110, the width of the second concave structure 11242 gradually decreases. It can also be understood that it has a side surface facing a light-emitting surface of the light-emitting unit 111. The side surface of the second concave structure 11242 is set with a signal line 114, which can directly reflect the light emitted from a portion of the side surface of the light-emitting unit 111 toward the light-emitting surface of the light-emitting unit 111, allowing the reflected light to be emitted directly. Thus, by setting the concave structure 1124 with the above structure, it is possible to further enhance the spotlight effect and improve light efficiency.

In addition, by arranging the opening 2420 of the second concave structure 11242 to connect the bottom surface 2410 of the first concave structure 11241, the entire concave structure 1124 can be continuous. The area of the signal line 114 covering the bottom surface and the side surface of the concave structure 1124 can be further increased. Thus, this further reduces resistance and improves signal consistency and connection stability.

In some embodiments, the second concave structure 11242 are evenly disposed in the concave structure 1124 to uniformly improve the light efficiency, thereby uniformly improving the overall display effect of the display panel 10.

For example, all concave structures in the display panel can be configured in a structural form mentioned above that the first concave structure 11241 and the second concave structure 11242 are interconnected, which is not limited here.

In some embodiments, continuing to refer to FIG. 19, in the display panel 10, the minimum distance between the concave structure 1124 and the base substrate 110 is H1. The distance between the side of the light emitting unit 111 away from the base substrate 110 and the base substrate 110 is Hp. The light-emitting unit 111 also includes a first electrode 214 located over one side of the first-type semiconductor layer 211 facing the base substrate 110. The distance between one side of the first electrode 214 away from the base substrate 110 and the base substrate 110 Hc and satisfies: H1>Hc and H1<Hp.

Distances between each of the structures and the base substrate 110 can be interpreted as distances between the corresponding structures and the plane of the base substrate 110. The plane of the base substrate 110 can be a surface of the base substrate 110 facing the light-emitting unit 111, as shown in FIG. 19. In other embodiments, the plane of the base substrate 110 can also be a surface of the base substrate 110 away from the light-emitting unit 111.

With this arrangement, the lowest height of the first film layer 112 with respect to the base substrate 110 can be equal to or greater than a height of the first electrode 214 and lower than a height of the light-emitting unit 111. The first electrode 214 is used as a reflective electrode. The concave structure 1124 of the first film layer 112 together with the signal line 114 to achieve a light concentration effect and improve the light efficiency. At the same time, the first film layer 112 is used to separate the first electrode 214 and the common electrode 113 to avoid short circuit.

The minimum distance H1 between the concave structure 1124 and the base substrate 110 can be interpreted as a distance between the lowest point of the bottom surface of the concave structure 1124 and the base substrate 110. In some embodiments, with reference to FIG. 21, the concave structure 1124 includes a first concave structure 11241 and a second concave structure 11242. At this time, the minimum distance H1 can be interpreted as the distance between the lowest point of the bottom surface of the second concave structure 11242 and the base substrate 110.

As shown in FIG. 4, when a layer of the light-emitting unit 111 furthest from the base substrate 110 is a second-type semiconductor layer 212, the side of the light-emitting unit 111 away from the base substrate 110 can be interpreted as one side of the second-type semiconductor layer 212 away from the base substrate 110. In other embodiments, when the layer of the light-emitting unit 111 furthest from the base substrate 110 is an electrode layer, one side of the light-emitting unit 111 away from the base substrate 110 can be interpreted as one side of the electrode layer away from the base substrate 110.

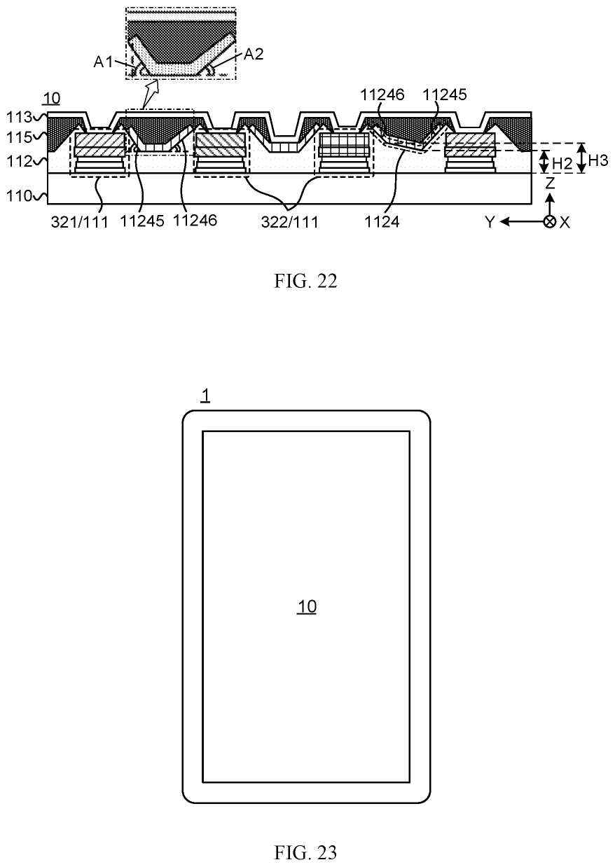

In some embodiments, FIG. 22 provides another schematic diagram of the display panel according to the present disclosure. Referring to FIG. 22, in the display panel 10, the light-emitting unit 111 includes a first color light-emitting unit 321 and a second color light-emitting unit 322, where an emission wavelength of the first color light-emitting unit 321 is greater than an emission wavelength of the second color light-emitting unit 322. The concave structure 1124 has a first side surface 11245 facing the first color light-emitting unit 321 and a second side surface 11246 facing the second color light-emitting unit 322. An inclination angle A1 of the first side surface 11245 is greater than or equal to an inclination angle A2 of the second side surface. In some embodiments, the minimum distance H2 between the first side surface 11245 and the base substrate 110 is less than or equal to the minimum distance H3 between the second side surface 11246 and the base substrate 110.

The inclination angle A1 of the first side surface 11245 can be interpreted as an angle between the first side surface 11245 and the plane of the base substrate 110. The inclination angle A2 of the second side surface 11246 can be interpreted as an angle between the second side surface 11246 and the plane of the base substrate 110. The two inclination angles in this embodiment are equal to or less than 90°.

Exemplarily, the first color light-emitting unit 321 can be a red light-emitting unit, and the second color light-emitting unit 322 can be at least one of a green light-emitting unit and a blue light-emitting unit.

Compared to the second color light-emitting unit 322, the first color light-emitting unit 321 has a longer emission wavelength, a lower frequency, and a lower energy. A large inclination angle of the side surface of the concave structure 1124, and/or, a deep side surface, that is, a small minimum distance between the side surface and the base substrate results in an excellent spotlight effect that the concave structure 1124 together with the signal line can achieve. Thus, by setting the inclination angle A1 of the first side surface 11245 larger than the inclination angle A2 of the second side surface 11246, and/or, the minimum distance H2 between the first side surface 11245 and the base substrate 110 larger than the minimum distance H3 between the second side surface 11246 and the base substrate 110, it is possible to utilize the spotlight effect based on the concave structure 1124 to enhance the light efficiency of the first color light-emitting unit 321, thereby balancing the overall display effect of the display panel and reducing the driving power consumption of the first color light-emitting unit 321. This is advantageous for reducing the overall power consumption of the display panel 10.

It can be understood that FIG. 22 exemplarily shows that the bottom surface of the concave structure 1124 can be a sloping surface. In other embodiments, the bottom surface of the concave structure 1124 can also be a step-like structure, and this is not limited here.

In some embodiments, the first color light-emitting unit 321 is a red light-emitting unit, and the second color light-emitting unit 322 can be a green light-emitting unit and a blue light-emitting unit. With respect to the plane of the base substrate, a height of the bottom surface of the concave structure between the red light-emitting unit and the green light-emitting unit is H11. A height of the bottom surface of the concave structure between the green light-emitting unit and the blue light-emitting unit is H22. A height of the bottom surface of the concave structure between the blue light-emitting unit and the red light-emitting unit is H33. In some embodiments, H11H22, and H11≤H33. Furthermore, H33≤H22, which balances the light efficiency of different color light-emitting units, enhances the overall display effect of the display panel, and reduces power consumption.

Embodiments of the present disclosure also provide a display apparatus. Exemplarily, FIG. 23 is a schematic structural diagram of a display apparatus according to various embodiments of the present disclosure. As shown in FIG. 23, the display apparatus 1 includes any one of the display panels 10 provided in the above embodiments with corresponding beneficial effects. To avoid redundancy, it is not further described here.

Exemplarily, the display apparatus includes but is not limited to a mobile phone, tablet, vehicle computer, smart wearable device with display function, and other structural components with display function.

Based on the same inventive concept, the present disclosure further provides a method for producing a display panel for forming any one of the display panels provided in the above embodiments.

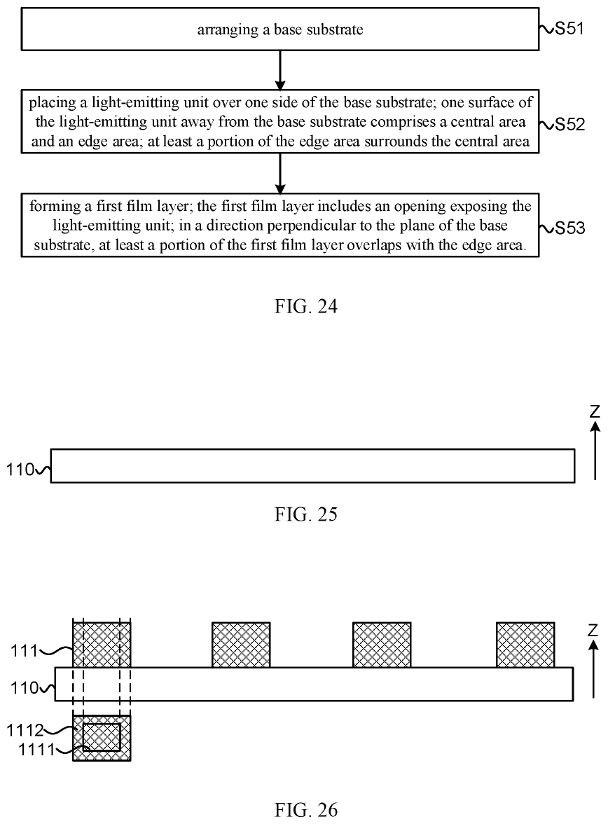

Exemplarily, FIG. 24 is a schematic flowchart of a manufacturing method for producing a display panel provided in the present disclosure. Referring to FIG. 24, the manufacturing method for producing the display panel includes the following steps.

S51, providing a base substrate.

Exemplarily, the base substrate cam be a circuit substrate connecting the light-emitting unit. The circuit substrate can be any type of circuit substrate known to those persons of ordinary skill in the art, without further elaboration or limitation.

Exemplarily, FIG. 25 shows a schematic structure of a circuit substrate. The base substrate 110 can include a patterned metal layer and a switch structure formed by a semiconductor layer, as well as a related circuit.

S52, arranging the light-emitting unit over one side of the substrate. The side surface of the light-emitting unit away from the base substrate includes a central area and an edge area. At least a portion of the edge area surrounds the central area.

In some embodiments, the light-emitting unit can be permanently arranged over one side of the base substrate or electrically connected to one side of the base substrate. The specific arranging and electrical connection methods can be any known methods to those persons of ordinary skill in the art.

Exemplarily, FIG. 26 shows a structure after this step, which includes the base substrate 110 and the light-emitting unit 111 configured over one side of the base substrate. The light-emitting unit 111 includes a central area 1111 and an edge area 1112. This defines the cutoff position of the first film layer for subsequent formation, i.e., the overlapping boundary position of the first film layer on the light-emitting unit.

S53, forming a first film layer. The first film layer is provided with an opening exposing the light-emitting unit. In the direction perpendicular to the plane of the base substrate, at least a portion of the first film layer overlaps with the edge area.

The first film layer covers the edge area of the light-emitting unit. The first film layer is utilized to cover and protect the edge area of the light-emitting unit, thereby addressing the issue of forming pits in the peripheral material layer (e.g., a flat layer) around the light-emitting unit. This helps to address the issue of short circuits occurring between the common electrode and other electrodes related to the light-emitting unit. Simultaneously, it addresses the occurrence of discontinuities of step area in the common electrode at the edge of the light-emitting unit to enhance circuit continuity.

Exemplarily, the first film layer can be a flat layer and/or a light-shielding layer.

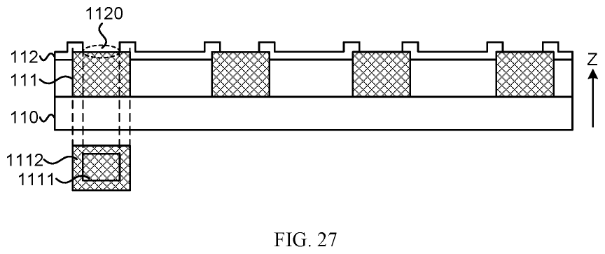

Exemplarily, FIG. 27 shows a structure after this step, which includes the first film layer formed over one side of the light-emitting unit 111 away from the base substrate 110. After this step, the manufacturing method can further include forming a common electrode. The electrical connection between the common electrode and the light-emitting unit is shown in FIG. 2.

The manufacturing method for producing the display panel provided in the present disclosure utilizes the first film layer to cover and protect the edge area of the light-emitting unit, thereby addressing the issue of short circuits occurring between the common electrode and other electrodes related to the light-emitting unit in the peripheral material layer (e.g., a flat layer) around the light-emitting unit. Simultaneously, it addresses the issue of discontinuities of step area occurring in the edge area of the light-emitting unit with the common electrode.

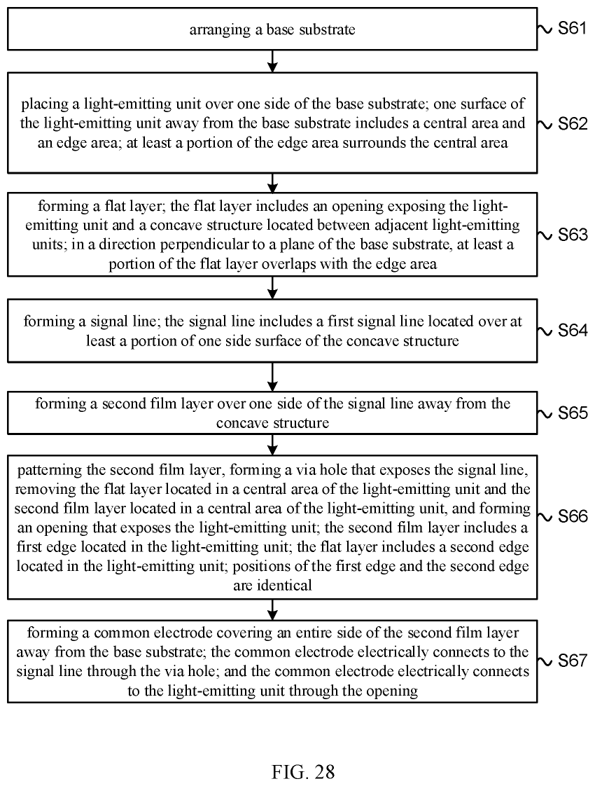

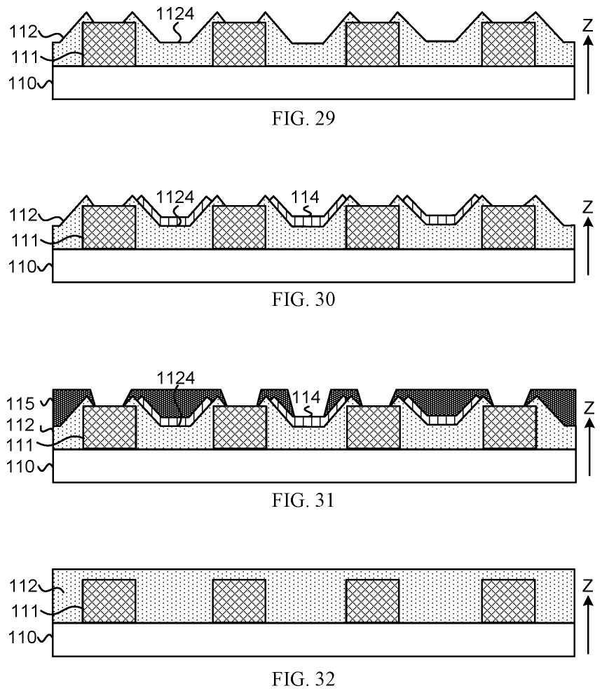

In some embodiments, the first film layer includes a flat layer, and the flat layer includes a concave structure. FIG. 28 is a schematic flowchart of another manufacturing method for producing a display panel provided in the present disclosure. Referring to FIG. 28, the manufacturing method for producing the display panel can include the following steps.

S61, providing a base substrate.

S62, arranging the light-emitting unit over one side of the substrate. The light-emitting unit over one side away from the base substrate includes a central area. At least portion of the edge area surrounds the central area.

S63, forming a flat layer. The flat layer is provided with an opening exposing the light-emitting unit and a concave structure located between adjacent light-emitting units. In the direction perpendicular to the plane of the base substrate, at least a portion of the flat layer overlaps with the edge area.

The previous three steps can be interpreted with reference to S51-S53.

It should be noted that in S63, the flat layer may also be a flat layer with a concave structure but without an opening.

In the actual manufacturing process, the flat layer can be a thin coating, i.e., the amount of coating of the flat layer is relatively small, such that the height of the flat layer with respect to the base substrate is higher than the first electrode of the light-emitting unit but lower than the height of the light-emitting unit. This naturally forms the concave structure. Subsequently, only photolithography is performed without grayscale treatment. By further modifying the concave structure, the edge area of the light-emitting unit will retain a thick flat layer. Therefore, the flat layer is not grayscale treated before being protected by the upper layer (e.g., the second film layer, specifically like the light-shielding layer), avoiding the issue of short circuits.

In other embodiments, the flat layer can be a thick coating. Thus, its height is above the light-emitting unit, as shown in FIG. 32. Subsequently, a grayscale mask lithography process is used to form the concave structure, and at the same time, the thick flat layer in the edge area of the light-emitting unit is retained.

S64, forming a signal line. The signal line includes a first signal line. The first signal line is located over at least a portion of the side surface of the concave structure.

Exemplarily, referring to FIG. 10 and FIG. 30, forming a signal line in the concave structure of the flat layer can achieve a spotlight effect, improving the light efficiency. Specific structural details can be referred to in the previous text.

Exemplarily, in this step, the signal line can be formed directly into a patterned line using a mask or can be formed by depositing a film over the entire surface first and then patterning.

S65, forming a second film layer on the side of the signal line away from the concave structure. Exemplarily, the second film layer can be a light-shielding layer.

S66, patterning the second film layer, forming a via hole exposing the signal line, removing the flat layer and the second film layer in the central area of the light-emitting unit, and forming an opening exposing the light-emitting unit. The second film layer includes a first edge located within the light-emitting unit, and the flat layer includes a second edge located within the light-emitting unit, and the position of the first edge is the same as the position of the second edge.

Exemplarily, a via hole processing is performed on the second film layer that overlaps with the signal line to form a via hole exposing the signal line. Organic film layers (including the flat layer and the second film layer) in the central area of the light-emitting unit are grayscale treated to form an opening exposing the light-emitting unit, as shown in FIG. 31. Exemplarily, the second film layer can be a light-shielding layer. The specific structural details can be referred to in the previous text.

S67, forming an entire layer of the common electrode on the side of the second film layer away from the base substrate, the common electrode electrically connected to the signal line through the via hole and electrically connected to the light-emitting unit through the opening.

An electrical connection between the common electrode and the light-emitting unit is achieved as well as an electrical connection between the common electrode and the signal line is achieved. Specific structural details can be referred to in the previous text.

In other embodiments, the manufacturing method for producing the display panel can include other steps known to those persons of ordinary skill in the art, such as packaging.

It should be noted that, in the present disclosure, relational terms such as “first” and “second” are used merely to distinguish one entity or operation from another, and do not necessarily imply any actual relationship or order between these entities or operations. Additionally, terms such as “comprising”, “including”, or any other variants are intended to cover non-exclusive inclusion, such that a process, method, article, or device comprising a series of elements includes not only those elements expressly listed but also other elements not expressly listed, or elements that are inherently present. In the absence of further limitations, the elements defined by statements such as “comprising a . . . ” do not exclude the presence of additional identical elements in processes, methods, articles, or devices that include the defined elements. The principles and novel features disclosed herein can be practiced in other embodiments without departing from the spirit and scope of the present disclosure.

The above is merely specific embodiments of the present disclosure, allowing those persons of ordinary skill in the art to understand or implement the present disclosure. Various modifications to these embodiments will be readily apparent to those persons of ordinary skill in the art, and the general principles defined herein can be applied to other embodiments without departing from the spirit or scope of the present disclosure.

What is claimed is:

1. A display panel, comprising
a base substrate;
a light-emitting unit located over one side of the base substrate, wherein one surface of the light-emitting unit away from the base substrate comprises a central area and an edge area; and at least a portion of the edge area surrounds the central area; and
a first film layer, wherein the first film layer comprises an opening exposing the light-emitting unit; and in a direction perpendicular to a plane of the base substrate, at least a portion of the first film layer overlaps with the edge area.

2. The display panel according to claim 1, wherein the first film layer is made up by an organic material.

3. The display panel according to claim 1, wherein
the light-emitting unit comprises a first-type semiconductor layer, a second-type semiconductor layer, and a light-emitting layer located between the first-type semiconductor layer and the second-type semiconductor layer; the second-type semiconductor layer is located over one side of the light-emitting layer away from the base substrate; and
the display panel further comprises a common electrode; the common electrode is located over one side of the first film layer away from the base substrate; the common electrode is electrically connected to the light-emitting unit through the opening.

4. The display panel according to claim 3, further comprising
a plurality of light-emitting units; and
a signal line located between at least some adjacent light-emitting units, wherein the signal line is electrically connected to the common electrode.

5. The display panel according to claim 4, wherein
a spacing between adjacent light-emitting units is Wg;
the signal line extends along a first direction, and a line width of the signal line in a second direction is W0, wherein the second direction is perpendicular to the first direction; and
(⅓)Wg≤W0<Wg.

6. The display panel according to claim 4, wherein
the signal line is located between the common electrode and the first film layer;
the display panel further comprises a second film layer; the second film layer is located between the signal line and the common electrode; and
the second film layer comprises a via hole; the common electrode electrically connects to the signal line through the via hole.

7. The display panel according to claim 6, wherein a transmittance of the second film layer is less than a transmittance of the first film layer.

8. The display panel according to claim 6, wherein
in the direction perpendicular to the plane of the base substrate, at least a portion of the second film layer overlaps with the edge area; and
the second film layer comprises a first edge that is located over the light-emitting unit; the first film layer comprises a second edge that is located over the light-emitting unit, wherein a position of the first edge and a position of the second edge are identical.

9. The display panel according to claim 6, wherein
the light-emitting unit comprises a plurality of first light-emitting units, a plurality of second light-emitting units, and a plurality of third light-emitting units; one first light-emitting unit of the plurality of first light-emitting units, one second light-emitting unit of the plurality of second light-emitting units, and one third light-emitting unit of the plurality of third light-emitting units form a virtual quadrilateral; the virtual quadrilateral comprises a first virtual quadrilateral; the first light-emitting unit is located at a first vertex of the first virtual quadrilateral; and the second light-emitting unit and the third light-emitting unit are respectively located at a second vertex of the first virtual quadrilateral, wherein the first vertex and the second vertex alternate and are spaced apart; and
the via hole is located inside a portion of the first virtual quadrilateral.

10. The display panel according to claim 9, wherein distances from the via hole to vertices of the first virtual quadrilateral are equal.

11. The display panel according to claim 9, wherein
an emission wavelength of the first light-emitting unit is shorter than an emission wavelength of the second light-emitting unit and/or an emission wavelength of the third light-emitting unit.

12. The display panel according to claim 6, wherein
the light-emitting unit is arranged at intervals along a third direction and/or a fourth direction, and the third direction intersects with the fourth direction; and
along the third direction or the fourth direction, a width of the light-emitting unit is W1, a distance between adjacent via holes is W2, and a spacing between adjacent light-emitting units is Wg, wherein W2≥3×(W1+Wg).

13. The display panel according to claim 6, further comprising a central display area and an edge display area, wherein at least a portion of the edge display area surrounds the central display area;
a distribution density of a via hole in the central display area is less than a distribution density of a via hole in the edge display area; and/or
an aperture of the via hole in the central display area is smaller than an aperture of the via hole in the edge display area.

14. The display panel according to claim 6, wherein an aperture D of the via hole satisfies: (⅕)W0≤D≤(⅘)W0; and W0 represents a line width of the signal line.

15. The display panel according to claim 4, wherein
the signal line is located between the common electrode and the first layer; and
the first layer comprises a concave structure; the signal line comprises a first signal line;
and the first signal line is located over at least a portion of one side surface of the concave structure.

16. The display panel according to claim 15, wherein
the concave structure comprises a first concave structure and a second concave structure; and
the second concave structure is located over one side of the first concave structure close to the base substrate; a width of one side of the second concave structure away from the base substrate is smaller than a width of one side of the second concave structure close to the base substrate.

17. The display panel according to claim 15, wherein
a minimum distance between the concave structure and the base substrate is H1;
a distance between one side of the light-emitting unit away from the base substrate and the base substrate is Hp;
the light-emitting unit further comprises a first electrode that is located over one side of the first-type semiconductor layer facing the base substrate; a distance between one side of the first electrode away from the base substrate and the base substrate is Hc; and
H1≥Hc,H1<Hp.

18. The display panel according to claim 15, wherein
the light-emitting unit comprises a first color light-emitting unit and a second color light-emitting unit; an emission wavelength of the first color light-emitting unit is greater than an emission wavelength of the second color light-emitting unit;
one side surface of the concave structure facing the first color light-emitting unit is a first side surface, and one side surface of the concave structure facing the second color light-emitting unit is a second side surface;
an angle between the first side surface and the plane of the base substrate is greater than or equal to an angle between the second side surface and the plane of the base substrate; and/or, a minimum distance between the first side surface and the base substrate is less than or equal to a minimum distance between the second side surface and the base substrate.

19. A display apparatus, comprising:
a display panel, comprising:
a base substrate;
a light-emitting unit located over one side of the base substrate, wherein one surface of the light-emitting unit away from the base substrate comprises a central area and an edge area; and at least a portion of the edge area surrounds the central area; and
a first film layer, wherein the first film layer comprises an opening exposing the light-emitting unit; and in a direction perpendicular to a plane of the base substrate, at least a portion of the first film layer overlaps with the edge area.

20. A method of forming a display panel, comprising:
arranging a base substrate;
placing a light-emitting unit over one side of the base substrate, wherein one surface of the light-emitting unit away from the base substrate comprises a central area and an edge area, and at least a portion of the edge area surrounds the central area; and
forming a first film layer, wherein the first film layer comprises an opening exposing the light-emitting unit; and in a direction perpendicular to the plane of the base substrate, at least a portion of the first film layer overlaps with the edge area.
